(19) United States
(12) Patent Application Publication
(10) Pub. No.: US 2009/0181283 A1
(43) Pub. Date: Jul. 16, 2009

(54) REGENERATION METHOD OF SEPARATOR FOR FUEL CELL, REGENERATED SEPARATOR FOR FUEL CELL AND FUEL CELL

(75) Inventors: Toshiki Sato, Kobe-shi (JP); Jun Hisamoto, Kobe-shi (JP); Jun Suzuki, Kobe-shi (JP); Yoshinori Ito, Kobe-shi (JP); Shinichi Tanifuji, Kobe-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Kobe Seiko Sho (Kobe Steel, Ltd.), Kobe-shi (JP)

(21) Appl. No.: 12/341,116

(22) Filed: Dec. 22, 2008

(30) Foreign Application Priority Data
Jan. 10, 2008 (JP) 2008-003754

(51) Int. Cl. H01M 2/00; B05D 5/12; C23C 16/513; B05D 3/04; C23C 14/34

(52) U.S. Cl. 429/34; 427/115; 427/569; 427/534; 204/192.1

(57) ABSTRACT

Disclosed herein is a method for regenerating a separator for a fuel cell in which the separator is composed of a substrate of Ti or Ti alloy and a conductive film formed thereon. The method includes a step of removing the conductive film from the separator for a fuel cell and also removing part of the surface of the substrate, thereby giving a regenerated substrate, and a step of forming a regenerated conductive film on the regenerated substrate. The conductive film and the regenerated conductive film are at least one species of noble metal or alloy thereof selected from the group of noble metals consisting of Au, Pt, and Pd, or an alloy composed of at least one species selected from the group of noble metals and one species selected from the group of metals consisting of Ti, Zr, Hf, Nb, Ta, and Si.

### BACKGROUND OF THE INVENTION

1. Field of the Invention

The present invention relates to a regeneration method of a separator for a fuel cell with a titanium or titanium alloy substrate and a regenerated separator for a fuel cell.

2. Description of the Related Art

In recent years, a fuel cell in which power is extracted using hydrogen, methanol and the like as the fuel is expected to be used as a source of energy that solves the earth environmental problems and the energy source problems. In particular, a polymer electrolyte fuel cell is investigated about application to a power source for a household cogeneration system and a portable device and to a fuel cell automobile, because of its operability in a low temperature and capability of reducing in size and weight.

Here, in a common polymer electrolyte fuel cell (hereinafter referred to as “fuel cell”), construction with catalyst layers functioning an anode and a cathode disposed in both sides of a solid polymer film which is electrolyte, gas diffusion layers on the outside thereof, and, further on their outside, separators shaped with grooves which become a fuel gas passage forms a basic unit (cell). In addition to forming the gas passage, the separator is required to be highly conductive to extract the generated current to the outside of the fuel cell.

In addition, the separator is required to be highly anti-corrosive because inside of the fuel cell is an acidic atmosphere, therefore carbon, a conductive resin and the like have been applied to such material. In order to reduce the size and weight of the fuel cell, however, formation of the separator with a metal which is easy in thinning is being investigated.

As a metallic separator excellent in corrosion resistance and conductivity, a separator using stainless steel, titanium (Ti) or titanium alloy for a substrate with the substrate being clad with noble metal of gold (Au) or the like (refer to Patent Documents 1, 2, for example), and a separator formed with an oxide film on a substrate film-formed with a middle layer comprising an alloy of Ti, Zr, Nb, Hf, Ta, and the like and with a conductive film comprising noble metal or carbon respectively (refer to Patent Documents 3, for example) have been developed. These separators with the substrate of stainless steel, Ti, or Ti alloy as described in Patent Documents 1-3 are excellent in strength and easy in thinning. In particular, because Ti and Ti alloy are light in weight, they greatly contribute in making the fuel cell light in weight by adopting as material for the substrate of the separator.

[Patent Document 1] Japanese Unexamined Patent Application Publication (JP-A) No. H10-228914

[Patent Document 2] JP-A-2001-6713

[Patent Document 3] JP-A-2004-185998

However, Ti and Ti alloy are inferior in workability and low in the yield in forming into a substrate, therefore they have a defect that the production cost of the substrate is high and the separator using such substrate becomes expensive. On the other hand, because the substrate comprising Ti or Ti alloy is excellent in durability, the substrate of the separator is not deteriorated even if the fuel cell reaches the end of its service life because of deterioration of a solid polymer film and catalyst electrodes. Consequently, it may be possible to reduce the separator cost by recovering the separator from the fuel cell that has reached the end of its service life and reuse it. However, in the recovered separator, although there is no deterioration such as corrosion in the substrate itself, agglomeration of noble metal may possibly occur in the film that coats the substrate. Also, when the film that coats the substrate comprises Zr, Ta, Nb, and the like, it may be possible that these Zr, Ta, Nb, and the like are oxidized in part. Although such film keeps the property applicable to the fuel cell, conductivity is deteriorated after use. Therefore, if the recovered separator is reused for the fuel cell as it is, the power generation property may possibly be lowered during use of the fuel cell due to deterioration of the separator.

Consequently, it may be possible to melt and cast the recovered separator as scrap and to form into the substrate again for rebuilding a new separator. However this means replacement only of the material sponge titanium to scrap, therefore the material cost can be lowered but sufficient cost reduction is not realized because it is not effective in improving the yield and the like.

### SUMMARY OF THE INVENTION

The present invention has been developed under consideration of the problems described above aiming, in reusing the separator recovered from the fuel cell at the end of its service life, to provide at a low cost the separator for a fuel cell without a problem in property compared with the separator newly manufactured from the substrate.

In order to address the problems described above, one aspect of the present invention is directed to a method for regenerating a separator for a fuel cell, in which the separator is composed of a substrate of Ti or Ti alloy and a conductive film formed thereon. The method includes a removing step of removing the conductive film from the separator for a fuel cell and also removing part of the surface of the substrate, thereby giving a regenerated substrate, and a film-forming step of forming a regenerated conductive film on the regenerated substrate, wherein the conductive film and the regenerated conductive film is at least one species of noble metal or alloy thereof selected from the group of noble metals consisting of Au, Pt, and Pd, or an alloy composed of at least one species selected from the group of noble metals and one species selected from the group of metals consisting of Ti, Zr, Hf, Nb, Ta, and Si.

The method according to this aspect can entirely remove an old conductive film and form again a conductive film (regenerated conductive film) with the same level of properties of the conductive film before use.

In the method according to this aspect, it is preferable to perform the film-forming step after performing an oxidizing step for forming an oxidized film on the surface of the regenerated substrate.

Thus, by forming the oxidized film on the surface of the substrate comprising Ti or Ti alloy, Ti does not absorb hydrogen and does not become embrittled even if it is reused for the fuel cell using hydrogen as the fuel, therefore it is possible to regenerate to the separator wherein the strength of the substrate is not lowered.

The oxidizing step described above is preferably performed by exposing the regenerated substrate in plasma comprising oxygen. According to such oxidizing step, an oxidized film with even thickness can be formed.

Or alternately, the oxidizing step may be performed by immersing the regenerated substrate in an aqueous solution comprising an oxidizing acid. By such oxidizing step, a passivated film, which is a kind of an oxidized film, is formed on the surface of the substrate comprising Ti or Ti alloy. Further, a nitric acid and a sulfuric acid can be applied as the oxidizing acid.

On the other hand, the removing step is preferably performed by generating plasma comprising at least one kind of a rare gas element selected from a group consisting of Ne, Ar, Kr, Xe in the circumstance of the separator for a fuel cell by applying negative bias voltage to the separator for a fuel cell and making ions of the rare gas element generated in the plasma collide with the surface of the separator for a fuel cell.

Or alternately, the removing step is preferably performed by irradiating an ion beam of the rare gas onto the surface of the separator for a fuel cell. Because these removing steps are performed in a vacuum process, a subsequent film-forming step and a precedent oxidizing step can be performed in a same processing chamber continuously, therefore it is preferable from a viewpoint of production.

In addition, the removing step and oxidizing step may be performed continuously by immersing the separator for a fuel cell in a solution comprising at least one kind of ions selected from a group consisting of Cl⁻, F⁻, NO₃⁻, SO₄²⁻.

If the separator for a fuel cell is immersed in a solution comprising Cl⁻, F⁻, NO₃⁻, SO₄²⁻ ions as described above, the conductive film can be removed and the passivated film is formed on the exposed surface of the substrate comprising Ti or Ti alloy, therefore an additional step for forming the oxidized film becomes unnecessary.

Furthermore, in each regeneration method of the separator for a fuel cell performing the oxidizing step described above, a heat treatment step for performing a heat treatment at a temperature of 300-600 DEG C. after the film-forming step is preferably performed.

Thus, by adding the heat treatment step after the film-forming step for the regenerated substrate on which the oxidizing step has been performed, the oxidized film (including passivated film) becomes a n-type semiconductor as oxygen contained diffuses into Ti or Ti alloy which is the regenerated substrate to become an oxygen deficiency type Ti oxide, therefore conductivity improves.

Further, in the film-forming step, it is preferable to form the regenerated conductive film by a sputtering method so that its thickness becomes 2-200 nm.

Thus, by controlling the film thickness of the regenerated conductive film, conductivity and corrosion resistance become excellent.

Another aspect of the present invention is directed to a regenerated separator for a fuel cell formed through the steps of removing from a separator for a fuel cell composed of a substrate of Ti or Ti alloy and a conductive film formed thereon, the conductive film and part of the surface of the substrate, and forming a regenerated conductive film on the thus removed separator for a fuel cell, wherein the conductive film and the regenerated conductive film are at least one species of noble metal or alloy thereof selected from the group of noble metals consisting of Au, Pt, and Pd, or an alloy composed of at least one species selected from the group of noble metals and one species selected from the group of metals consisting of Ti, Zr, Hf, Nb, Ta, and Si, and wherein the conductive film and part of the surface of the substrate are removed by making ions of at least one kind of a rare gas element selected from a group consisting of Ne, Ar, Kr, Xe collide with the surface of the separator for a fuel cell under reduced pressure.

In such regenerated separator for a fuel cell, the old conductive film is entirely removed and the conductive film of the property level same to that of the conductive film before use is formed on the substrate without deterioration of property, consequently, it can be applied to a fuel cell like a separator for a fuel cell newly manufactured from a substrate.

Also, in the regenerated separator for a fuel cell, it is preferable that an oxidized film is formed on the surface of the separator for a fuel cell wherein the conductive film and part of the surface of the substrate are removed.

In such regenerated separator for a fuel cell, because the oxidized film is formed on the surface of the substrate comprising Ti or Ti alloy, even if exposed to hydrogen, Ti does not absorb hydrogen and is not embrittled and the strength of the substrate is not lowered, therefore the separator can be utilized for fuel cells using hydrogen as the fuel.

Further, in the regenerated separator for a fuel cell, the conductive film and part of the surface of the substrate may be removed by immersing the separator for a fuel cell in a solution comprising at least one kind of ions selected from a group consisting of Cl⁻, F⁻, NO₃⁻, SO₄²⁻ instead of making ions of a rare gas element collide with the surface of the separator for a fuel cell.

In such regenerated separator for a fuel cell, because the old conductive film is entirely removed and the passivated film is formed by immersing in the solution, utilization to the fuel cell using hydrogen as the fuel is possible without going through a process of newly forming an oxidized film.

Further, it is preferable that each of the regenerated separator for a fuel cell wherein the oxidized film (including passivated film) is formed is subjected to a heat treatment at a temperature of 300-600 DEG C. after the regenerated conductive film is formed.

Thus, in the regenerated separator for a fuel cell formed with the oxidized film, by performing the heat treatment after regenerated conductive film is formed, the oxidized film (including passivated film) becomes the hydrogen deficiency type Ti-oxide as oxygen contained diffuses into Ti or Ti alloy, which is the substrate, and becomes a n-type semiconductor, therefore conductivity improves.

Also, the fuel cell in relation with the present invention is characterized in using each of the regenerated separator for a fuel cell described above.

With such fuel cell, the performance of the same level to that of when a separator for a fuel cell newly manufactured from a substrate is applied can be obtained.

### (Effects of the Invention)

In accordance with the regeneration method of the separator for a fuel cell in relation with the present invention, the separator recovered from the fuel cell at the end of its service life can be regenerated at a low cost to the separator for a fuel cell without a problem in property compared with the separator newly manufactured from the substrate. The regenerated separator for a fuel cell in relation with the present invention can be used to fuel cells like a separator newly manufactured from a substrate. The fuel cell in relation with the present invention has the performance of the same level to that of the fuel cell using newly manufactured separator, and the cost can be lowered.

### BRIEF DESCRIPTION OF THE DRAWINGS

Embodiment(s) of the present invention will be described in detail based on the following figures, wherein:

FIG. 1 is an exploded perspective view explaining the constitution of the fuel cell in relation with the present embodiment;

FIG. 2A is a plan view of the separator in relation with the present embodiment;

FIG. 2B is a partial enlarged view of the section A-A in FIG. 2A;

FIG. 3 is a drawing showing the outline constitution of the composite type treatment system; and

FIG. 4 is a drawing schematically explaining the measuring method of contact resistance.

### DESCRIPTION OF THE PREFERRED EMBODIMENTS

The regeneration method of the separator for a fuel cell (hereinafter referred to as “separator”) and the regenerated separator for a fuel cell (hereinafter referred to as “regenerated separator”) in relation with the present invention will be described referring to the drawings.

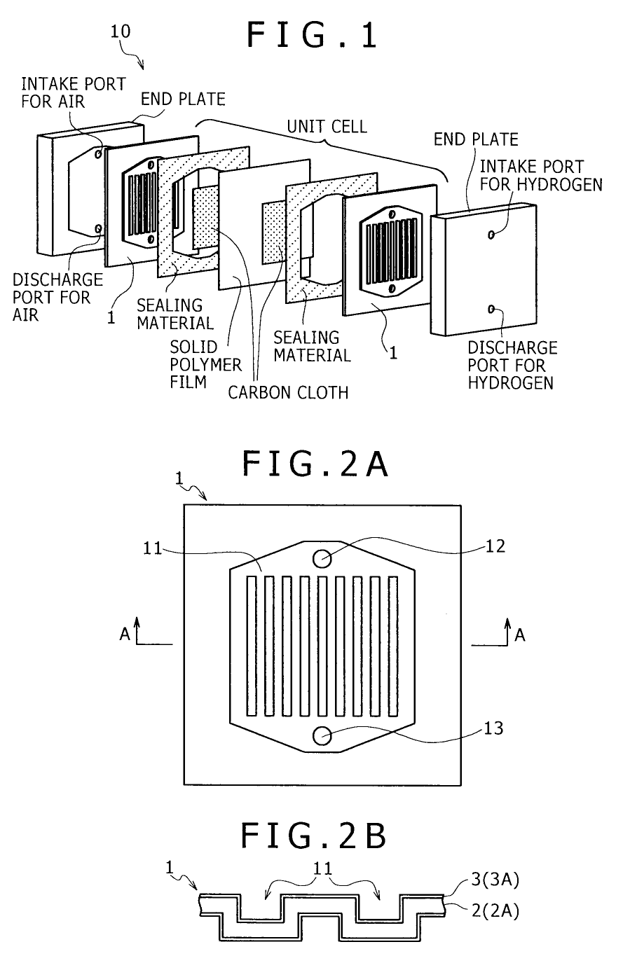

First, the constitution of the polymer electrolyte fuel cell (hereinafter referred to as “fuel cell”) and the separator used for the fuel cell will be described. FIG. 1 shows an exploded perspective view explaining the constitution of the fuel cell in relation with an embodiment in accordance with the present invention. In this regard, the overall constitution of this fuel cell is same with that of known common fuel cell.

As shown in FIG. 1, a fuel cell 10 comprises a solid polymer film, carbon cloths disposed in both sides thereof, separators 1, 1 disposed further outside thereof, and end plates sandwiching them from both sides. Although two separators 1, 1 and the portion sandwiched by them is a unit cell of the fuel cell and the fuel cell shown in FIG. 1 is constituted of one unit cell, in general, the fuel cell is constituted, according to the generating power amount and the like, by stacking a plurality of unit cells, two end plates sandwiching the stacked unit cells (cell stack, not shown) from both ends, and fastening members such as bolts and the like (not shown) fixing the cell stack. Also FIG. 1 shows an anode in the right side and a cathode in the left side.

The solid polymer film is an electrolyte and can be used without limitation in particular as far as it is a film with an action to transfer a proton generated in the anode to the cathode, for example, a fluorine-based polymer film containing a sulfone group can be suitably used. Also, on both sides of the solid polymer film, platinum (Pt) catalyst and the like (not shown) are coated and act as an anode and a cathode respectively.

The carbon cloth is a gas diffusion layer, and the anode side carbon cloth is for supplying hydrogen gas whereas the cathode side carbon cloth is for supplying air (oxygen) from gas channel grooves described below of the separator 1 facing respectively to the solid polymer film evenly.

The separator 1 is rectangular in plan view with a thin plate shape, grooves for channels (gas channel grooves) of gas (hydrogen gas or air) is formed on the face of the side opposing the carbon cloth, and an intake port and a discharge port for fuel (hydrogen) or air (oxygen) are penetratingly formed in the groove. The gas channel grooves are shaped by press working and the like, and, in this case, the back side (the side opposing the end plate) becomes a shape wherein projected parts are formed along the gas channel grooves. The separator 1 is constituted of material having conductivity for extracting electric power from the unit cell and high corrosion resistance to cope with an acid atmosphere inside the unit cell. The detail of the constitution of the separator 1 will be described later.

In addition, in the present embodiment, in a plan view, because the carbon cloth is of a size of the range opposing the gas channel grooves part of the separator 1 and is smaller than the solid polymer film and the separator 1, the end face of the unit cell is sealed by interposing a sealing material comprising a silicone resin and the like with the region where the carbon cloth is disposed being hollowed out between the solid polymer film and the separators 1, 1 in both sides thereof respectively.

The end plate is a plate material of generally same shape with or a little larger than the separator 1 in a plan view, and has the strength required for fixing the cell stack. Also, similarly to the separator 1, it is provided with conductivity for extracting electric power from the unit cell (cell stack) and high corrosion resistance to cope with an acid atmosphere. As such material, a SUS plate with Au plating, for example, is applied. In the end plate, an intake port and a discharge port of fuel (anode side) or air (cathode side) are penetratingly formed in the same position in a plan view of the intake port and the discharge port of fuel or air formed in the separator, and both intake ports and both discharge ports communicate with each other respectively when sandwiching the cell stack. O-rings (not shown) are imposed for sealing between both of these intake ports and discharge ports respectively of the end plate and the separator 1 for preventing gas leakage, and an O-ring groove (not shown) is provided in the end plate. Also, so that the projected part on the back side of the gas channel grooves described above of the separator 1 may not hinder fastening of the end plate, faced grooves are provided in the face of the end plate which is inner side of the unit cell. Further, in the end plate, fitting ports (not shown) for fitting the fastening members such as bolts are formed in four corners, for example.

Next, the detail of the constitution of the separator in relation with the present invention will be described. FIGS. 2A and 2B are external schematic views of the separator in relation with the present embodiment, and FIG. 2A is a plan view, whereas FIG. 2B is a partial enlarged view of the section A-A in FIG. 2A. Also, the constitution of the separator 1 in relation with the present embodiment is common for prior to regeneration (recovered separator for a fuel cell) and after regeneration (regenerated separator for a fuel cell).

The separator 1 has the gas channel grooves 11 in the face which is the inner side of the unit cell when assembled into the unit cell (the face opposing the carbon cloth). Within the gas channel grooves 11, the intake port 12 and the discharge port 13 for hydrogen or air are penetratingly formed in the plate thickness direction of the separator 1. In this connection, the shapes in a plan view (FIG. 2A) and a cross-sectional view (FIG. 2B) of the gas channel grooves 11 and the shape and position of the intake port 12 and the discharge port 13 (as shown in FIG. 2A) are only examples and are not to be limited to this shape. Further, the separator 1 is constituted of the substrate 2 and the conductive film 3 coating entire surface of the substrate 2 (both faces including inside the gas channel grooves 11, end faces, inner peripheral surfaces of the intake port 12 and the discharge port 13).

The substrate 2 is formed of Ti or Ti alloy because the material is with high strength, light in weight, excellent in corrosion resistance, and can stand the regeneration method in accordance with the present invention. Specifically, pure Ti of kinds 1-4 and Ti alloy such as Ti—Al, Ti—Ta, Ti-6Al-4V, Ti—Pd, and the like as stipulated in JIS H 4600 can be used. Also, from the points of strength, workability and the like, the thickness of the substrate 2 is preferably in the range of 0.1-0.2 mm. Further, the substrate 2 is formed into the shape of the separator 1 (the shape with gas channel grooves 11, the intake port 12 and the discharge port 13 being formed) by a known method such as rolling and press working from Ti or Ti alloy described above.

The conductive film 3 is formed of a noble metal or a noble metal alloy comprising at least one kind selected from a noble metal group consisting of Au, Pt, Pd, or an alloy comprising at least one kind selected from the noble metal group described above and at least one kind selected from a metal group consisting of Ti, Zr, Hf, Nb, Ta, Si. These noble metal and alloy containing noble metal have conductivity for extracting generated electric power and corrosion resistance to cope with an acid atmosphere inside the fuel cell. Further, the conductive film 3 can be formed on the surface of the separator 1 by a known method such as plating, PVD method, sputtering method, and the like.

The thickness of the conductive film 3 is preferably 2-200 nm. If it is below 2 nm, conductivity and corrosion resistance of the separator 1 may possibly become insufficient. On the other hand, even if the conductive film 3 with the thickness exceeding 200 nm is coated, the property of conductivity and the like is saturated and removal of the conductive film (removing step described later) takes time in regeneration of the separator 1 which results in high regeneration cost. The thickness of the conductive film 3 is more preferably 3-150 nm, and most preferably 5-100 nm.

Also, it is preferable to provide with an oxidized film (not shown) on the surface of the substrate 2, that is between the substrate 2 and the conductive film 3. In particular, in the case of the separator 1 applied to the fuel cell using hydrogen as the fuel, if there is no oxidized film, Ti constituting the substrate 2 absorbs hydrogen and is embrittled, therefore, the strength of the substrate 2 lowers. Further, removal of the conductive film in regeneration of the separator 1 (removing step described later) includes removal of the oxidized film as well. In addition, the oxidized film includes the passivated film naturally formed on the surface of the substrate 2 when the substrate 2 is manufactured of Ti or Ti alloy in the atmospheric air.

The thickness of the oxidized film is preferably 0.5-10 nm. If it is below 0.5 nm, effect of preventing absorption of hydrogen to the substrate 2 is insufficient. On the other hand, if the oxidized film is too thick, it takes long time in forming such oxidized film (oxidation treatment) and conductivity of the separator lowers. Also, in recovering and regenerating such separator, removal of the conductive film and the oxidized film (removing step described later) takes long time which results in high regeneration cost. Further, in the case of the separator 1 applied to the fuel cell using methanol as the fuel, the oxidized film can optionally be absent, and, for example, the conductive film 3 may be formed after removing the passivated film naturally formed in the atmospheric air.

It is preferable that the oxidized film (including the passivated film) is subjected to a heat treatment. By the heat treatment, the oxidized film becomes an oxygen deficiency type Ti-oxide with oxygen contained being diffused into Ti or Ti alloy which is the substrate 2 and becomes n-type semiconductor which results in improvement in conductivity. Further, the heat treatment is performed after forming the conductive film 3, and the detail of its treatment condition and the like will be described later.

Next, the regeneration method of the separator in relation with the present invention will be described.

First, the fuel cell which reached the end of its service life or whose predetermined working time elapsed or the like is disassembled and the separator is recovered. Then, the conductive film and part of the surface of the substrate are removed (removing step) from the recovered separator, and a new conductive film is formed on the substrate (film-forming step). Also, it may be possible to form the conductive film after the oxidized film is formed (oxidizing step) on the substrate exposed by the removing step. Further, it may be possible to perform a heat treatment (heat treatment step) on the substrate with the conductive film being formed after the oxidized film is formed as described above. Below, respective step will be described in detail.

(Removing Step)

In the recovered separator, the conductive film 3 on the surface is to be entirely removed, and Ti or Ti alloy of the substrate 2 is to be exposed. For that, the surface layer of the substrate 2 including the oxidized film such as the passivated film is to be removed as well. The substrate 2 whose surface layer has been removed by the removing step is distinguished from new substrate 2 and is referred to as regenerated substrate 2A. In this regard, if the separator 1 in FIGS. 2A and 2B is the regenerated separator, the substrate 2 becomes the regenerated substrate 2A. The removing thickness of the substrate 2 in the removing step is preferably 10-5,000 nm from the original surface of the substrate 2. The reason is that, if it is below 10 nm, the oxidized film possibly may not be removed perfectly, and it is more preferably 20 nm or above, most preferably 40 nm or above. On the other hand, if removed over 5,000 nm, the thickness of the separator 1 (substrate 2) decreases over 10 μm in total of top and back surfaces, therefore, accuracy of the sheet thickness and the shape of the gas channel grooves 11 and the like are affected. Therefore, it is more preferably 2,500 nm or below, and most preferably 1,000 nm or below. In addition, as the removing thickness in regeneration at one time becomes thin, the number of times of regeneration can be increased. For example, even if a layer of the depth of approximately 100 nm (=0.1 μm) from the original surface of the substrate 2 with the sheet thickness 100 μm is removed, reduction of the thickness of the regenerated substrate 2A is 0.2% in total of top and back surfaces and the thickness hardly changes, the strength of the regenerated substrate 2A and the shape of the gas channel grooves 11 are not affected, and the conductive film 3 and the oxidized film can be securely removed.

Further, it is preferable to carry out inspection of the recovered separator on sheet thickness, flatness and the like prior to performing regeneration in accordance with the regeneration method of the separator in relation with the present invention, and to remove the separator of thin sheet thickness or with deflection. For example, if the thickness is below 90% compared to a new separator, it is judged to be unsuitable to regeneration and is used for reutilization as scrap. Below, the removing method of the conductive film and the oxidized film will be described for respective embodiment.

Removal of the conductive film and the oxidized film from the separator can be performed by applying negative bias voltage to the substrate in one or more kind of rare gas atmosphere selected from Ne, Ar, Kr, Xe thereby generating plasma of these rare gas elements in the circumstance of the separator, and making the ions of one or more kind selected from Ne, Ar, Kr, Xe collide to the surface of the separator. With respect to the method of applying voltage to the separator, there are methods to apply direct current between a metal container containing the separator and rare gas and the substrate so that the substrate becomes minus, or to apply the high frequency to the separator, however, as far as plasma is formed, any method can be used. Also, for forming plasma, the pressure of the rare gas should be adjusted, and it is preferable to make it 0.13-10 Pa. The reason is that, plasma is not generated when it is below 0.13 Pa, and the effect saturates when it exceeds 10 Pa.

In addition, the conductive film and the oxidized film can be removed from the separator also by irradiation of the ions of one or more kind selected from Ne, Ar, Kr, Xe onto the surface of the separator by an ion gun.

In the case of the removal processing by such ion beam irradiation, by controlling accelerating voltage, gas pressure, irradiation time and the like constant, the thickness of removed Ti or Ti alloy can be controlled with accuracy of approximately several tens of nm, therefore, the removal processing can be carried out almost without decreasing the thickness of the substrate 2. Further, it is also possible to adjust the removing thickness by irradiation time and the like depending on whether the recovered separator comprises the oxidized film or not. Also, because removal of thin thickness is possible, regeneration in multiple times becomes possible as described previously.

Furthermore, in the case of regeneration into the separator comprising the oxidized film, if the recovered separator is immersed in the solution comprising Cl⁻, F⁻, NO₃⁻, SO₄²⁻ ion, the conductive film and the oxidized film can be removed, and the passivated film is formed on the surface of the exposed regenerated substrate 2A comprising Ti or Ti alloy, therefore, an additional step for forming the oxidized film becomes unnecessary.

As such solution, sulfuric acid, nitric acid, hydrofluoric acid, and a mixed acid thereof and the like can be cited, for example, hot sulfuric acid (10% aqueous solution, 80 DEG C.), an aqueous solution of nitric-hydrofluoric acid of 0.25% HF+1.0% HNO₃. Also, according to material and thickness of the conductive film to be removed, kind of acid, concentration, temperature, immersing time can be properly combined.

(Film-Forming Step)

On the regenerated substrate 2A wherein the conductive film 3 (and the surface of the substrate 2) is removed, the conductive film (regenerated conductive film 3A) is formed again. This regenerated conductive film 3A is formed by the material, film thickness, and film-forming method same with those for the conductive film 3 described previously, and the detail is omitted. In this regard, when the removing step is carried out by the method by the ion of the rare gas element described previously (plasma atmosphere or the ion gun), it is possible to perform sputtering in the same vacuum processing chamber continuously and to form the regenerated conductive film 3A. In particular, when regenerated into the separator without the oxidized film, the regenerated substrate 2A is not exposed to the open air, therefore, the passivated film is not formed on the surface and only regenerated conductive film can be formed.

(Oxidizing Step)

In regeneration into the separator comprising the oxidized film, instead of performing the oxidizing step continuously from the removing step by immersing the recovered separator in an acid as described above, it may be possible to form the oxidized film by immersing the regenerated substrate 2A in an oxidizing acid such as nitric acid and sulfuric acid after the removing step by the ion beam irradiation and the like. Also, the regenerated substrate 2A may be exposed to the plasma containing oxygen (hereinafter referred to as O₂ plasma). Although the oxidized film is formed also by exposing the regenerated substrate 2A to the open air after the removing step, it is difficult to always form the oxidized film with a specific thickness by the influence of temperature, humidity, leaving time. In particular, when the removing step is carried out by the method by the ion of the rare gas element described above, the conductive film can be formed continuously in the same vacuum processing chamber and the regenerated conductive film 3A can be formed by performing the film-forming step by sputtering continuously further, therefore, it is preferable from a viewpoint of production.

By exposing the regenerated substrate 2A to O₂ plasma, the same situation arises as that when exposed to an oxygen atmosphere of high pressure because oxygen in the plasma is activated even under low pressure, and by adjusting pressure and output required for generation of plasma, the oxidized film with a specific thickness can be formed. O₂ plasma can be generated by introducing oxygen into the vacuum processing chamber containing the regenerated substrate 2A, and either by applying direct current between the regenerated substrate 2A and the chamber so that the regenerated substrate 2A becomes minus, or by applying the high frequency to the regenerated substrate 2A or electrodes for exclusive use. The pressure inside the vacuum processing chamber (oxygen atmosphere) at this time is preferably 0.13-10 Pa. The reason is that, plasma is not generated when it is below 0.13 Pa, and the plasma generation effect saturates when it exceeds 10 Pa.

(Heat Treatment Step)

In regenerating the recovered separator into the separator comprising the oxidized film, it is preferable to perform the heat treatment after the film-forming step for improving conductivity of the oxidized film as described previously. The heat treatment temperature is preferably 300-600 DEG C. If it is below 300 DEG C., diffusion of oxygen is slow and conductivity is not improved. On the other hand, if it exceeds 600 DEG C., diffusion of oxygen is too fast and the oxidized film vanishes, therefore, hydrogen absorption prevention effect is eliminated.

In the heat treatment step, if the regenerated conductive film 3A is of an alloy comprising Ti, Zr, Hf, Nb, Ta, Si, oxidation of the regenerated conductive film 3A proceeds in an atmosphere with high oxygen partial pressure, therefore, the oxygen partial pressure is preferably 0.133 Pa or below, more preferably 0.0133 Pa or below. On the other hand, if the regenerated conductive film 3A is noble metal or noble metal alloy comprising Au, Pt, it can be heat treated in the open air because it is not oxidized, but durability becomes higher as the oxygen partial pressure becomes lower. It is preferably 1.33 Pa or below, more preferably 0.133 Pa or below. However, if the regenerated conductive film 3A is Pd or noble metal alloy comprising Pd and when heated in the open air, Pd is oxidized and conductivity is deteriorated, therefore, the oxygen partial pressure is preferably 1.33 Pa or below, more preferably 0.665 Pa or below, and most probably 0.133 Pa or below.

Also, if the heat treatment temperature is made T (DEG C.), the heat treatment time t (min) is, when 300≦T≦600, preferably (420−T)/40≦t≦2/3·exp{(806.4−T)/109.2} and t≧0.5. If the heat treatment time is shorter than the range described above, improvement of conductivity of the oxidized film is insufficient, and, on the other hand, if the heat treatment time exceeds the range described above, the oxidized film may possibly be eliminated. For example, when the heat treatment temperature is 400 DEG C., the heat treatment time is preferably 0.5-41.3 min.

### EXAMPLE

Although the best mode to carry out the present invention has been described above, the examples wherein the effects of the present invention were confirmed will be described specifically below. In this regard, the present invention is not to be limited to these examples.

### Example 1

### {Manufacturing of Separator}

First, the separator before regeneration (new separator) was manufactured from the substrate.

(Substrate)

A sheet of 0.15 mm thickness comprising pure Ti (ASTM G1) was shaped with the gas channel grooves 11, intake port 12, and discharge port 13 as shown in FIG. 2A by press forming, and the substrate 2 with the size of 10 cm×10 cm was manufactured.

(Formation of Oxidized Film)

By immersing the substrate manufactured in an aqueous solution of nitric-hydrofluoric acid, mixture of 0.25% (wt %, hereinafter the same) HF and 1.0% HNO₃, for 1 min at ordinary temperature, a passivated film was formed on the surface. Also, after immersion, the substrate was water washed and dried.

(Formation of Conductive Film)

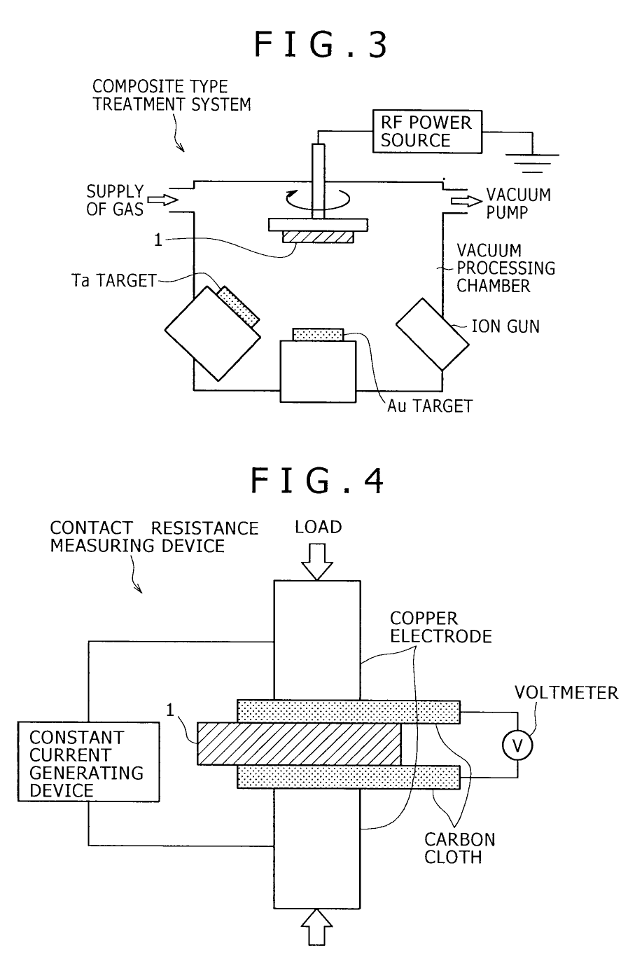

In the composite type treatment system having a sputtering device shown in FIG. 3, an Au target with 4 in. diameter×5 mm thickness was used. The substrate after forming the oxidized film was disposed in a position opposing the target (target-substrate distance: 10 cm), and Ar gas was introduced (Ar gas pressure: 0.266 Pa) after inside of the processing chamber was evacuated to 1.3×10⁻³ Pa or below. Then, while the substrate was rotated at the rotational speed of 15 rpm, an Au film (conductive film 3) was formed to 10 nm film thickness by 100 W output. Further, also on the back side of the substrate, the Au film was formed in a similar manner.

Also, the film-forming time was decided by; performing sputtering on a glass substrate masked in part beforehand under the condition same to the above changing the film-forming time, peeling off the masking after film-forming, measuring the sputtering film thickness by measuring the step of the surface of the film and the surface of the glass substrate by a surface roughness measuring tool, calculating the film-forming speed based on correlation of the film-forming speed and the film thickness, and dividing the desired film thickness by the film-forming speed.

As shown in FIG. 4, the substrate after film-forming was sandwiched by the carbon cloths at part of the gas channel grooves 11 from both sides and was sandwiched by flat electrodes of Cu with 1 cm² area from thereon under 4 kg load, the voltage between the carbon cloths generated when 0.1 A current was passed to the Cu electrodes was measured, and contact resistance was obtained. As shown in FIG. 1, the contact resistance was 27 mΩ.

(Heat Treatment)

The substrate after film-forming was placed in a heat treatment furnace and was heated at 400 DEG C. for 3 min after inside of the furnace was evacuated to 1.3×10⁻³ Pa or below, and a new separator was manufactured. Contact resistance of the new separator manufactured was measured by the method similarly to that for the substrate before heat treatment described previously. As shown in Table 1, the contact resistance was 4.6 mΩ, and improvement in conductivity by the heat treatment was recognized. Also, the criterion of the contact resistance of the separator was set to 15 mΩ or below.

### {Application to Fuel Cell and Operation}

The new separator manufactured was assembled into the fuel cell shown in FIG. 1. In other words, a solid polymer film (Nafion 1135) coated with a platinum catalyst was sandwiched by the carbon cloths and the sealing materials made of silicone resin with the manufactured separators sandwiching from both sides thereof, which was further sandwiched by the end plates comprising the stainless steel plates with Au plating, thereby the fuel cell was assembled. To the intake port and discharge port of the end plates, the introducing pipe and the discharging pipe of hydrogen gas in anode side and the introducing pipe and the discharging pipe of air in cathode side were connected respectively.

The fuel cell assembled was held under heating to 80 DEG C., and hydrogen (99.999% purity) and air were introduced to the fuel cell at the pressure of 2,026 hPa (2 atm) with the dew point thereof being adjusted to 80 DEG C. by going through the hot water. Then, the current passing the separator was made constant at 300 mA/cm using a cell performance measuring system (model 890CL made by Scribner Associates Inc.), and 5,000 hours of power generation operation was conducted. The voltage in the early stage of operation and after 5,000 hours of operation as well as the drop amount Δ of the voltage are shown in Table 1. After the 5,000 hours of operation, the fuel cell was disassembled, the separators were recovered, and the contact resistance was measured by the method similar to that before operation. The contact resistance and the increased amount Δ from the contact resistance before operation are shown in Table 1.

As shown in Table 1, the generation voltage in the early stage and the final stage of the operation were 0.612 V, 0.608 V respectively, and the drop amount was 0.004 V. Also, the criterion for the generation voltage is 0.6 V or above in the early stage of the operation and 0.01 V or below for the drop amount. Further, the contact resistance was 5.1 mΩ which is 0.5 mΩ increase compared with that before operation, but no significant drop in conductivity was recognized.

### {Regeneration of Separator}

Next, the recovered separator was regenerated in accordance with the method in relation with the present invention.

(Removing Step)

The recovered separator was placed in the composite type treatment system equipped with the ion gun (ION SOURCE, 3 cm, made by Ion Tech Inc.) shown in FIG. 3 (ion gun—separator distance: 20 cm). After inside of the processing chamber was evacuated to 1.3×10⁻³ Pa or below, Ar gas (99.999% purity) was introduced at the flow rate of 5 sccm until the pressure inside the treatment chamber became 0.02 Pa. Then, an Ar ion beam was irradiated onto the surface of the separator by actuating the ion gun under the conditions described below while the separator was rotated at a rotational speed of 15 rpm so that the ion beam is irradiated onto entire surface of the separator. The ion gun was positioned so that the center of the ion beam hits the point 2.5 cm apart from the center of the surface of the separator, and irradiated the ion beam from the direction of 45° onto the surface of the separator.

(Ion Gun Working Condition)
Filament current: 4 A
Discharge current: 0.9 A
Acceleration voltage: 500 V
Beam voltage: 500 V
Irradiation time: 5 min

(Oxidizing Step)

Next, after inside of the processing chamber was evacuated again to 1.3×10⁻³ Pa or below, oxygen (O₂) was introduced until the pressure inside the treatment chamber became 2.66 Pa, and O₂ plasma was generated for 5 min by applying high frequency (13.56 MHz) to the separator (generated substrate 2A).

(Film-Forming Step)

Then, after inside of the processing chamber was evacuated again to 1.3×10⁻³ Pa or below, Ar gas was introduced until the pressure inside the treatment chamber became 0.266 Pa, and an Au film (regenerated conductive film 3A) was formed to 10 nm film thickness under the condition same with that in manufacturing the new separator. Further, also on the back side of the separator, the removing step—the film-forming step were performed in the similar manner.

Further, the removing thickness of the surface of the substrate by the removing step was calculated by; cutting a pure Ti substrate (0.15 mm thickness), which is same with the material of the substrate of the present example, to 2 cm×5 cm, measuring the weight of the substrate after performing formation of the oxidized film under the condition same with that of the step for manufacturing the new separator, further performing formation of an Au film with 10 nm film thickness, heat treatment and ion beam irradiation similarly with the above, measuring the weight again, and dividing the weight obtained by deducting this weight from the initial weight by the area of the substrate and density of Ti. The removing thickness of the surface of the substrate thus calculated was 56 nm per one side.

(Heat Processing Step)

Finally, heat treatment was performed under the condition same with that of manufacturing the new separator, and the regenerated separation was manufactured. The contact resistance before and after the heat treatment step was measured by the method similar to that for the new separator. As shown in Table 1, respective contact resistance was 22 mΩ and 4.2 mΩ, improvement in conductivity of the same level with that in the heat treatment for the new separator was realized by the heat treatment, and the regenerated separator obtained was recognized to have the conductivity of the same level with that of the new separator.

(Reuse for Fuel Cell and Operation)

Similarly to the new separator, the regenerated separator was assembled into the fuel cell shown in FIG. 1, and 5,000 hours of power generation operation was performed. The voltage in the early stage of operation and after 5,000 hours of operation as well as the drop amount Δ of the voltage are shown in Table 1. After the 5,000 hours of operation, the fuel cell was disassembled, the separators were recovered, and the contact resistance was measured by the method similar to that before operation. The contact resistance and the increased amount Δ from the contact resistance before operation are shown in Table 1.

As shown in Table 1, the generation voltage in the early stage and the final stage of operation were 0.611 V, 0.606 V respectively, and the drop amount was 0.005 V. Also, the contact resistance was 4.8 mΩ which was 0.6 mΩ increase compared with that before operation. Thus, the properties of the same level with those of the new separator were obtained with respect to both of the generation voltage and the drop amount by the operation and the contact resistance and the increased amount by the operation. Further, by observation of the cross-section of the recovered separator by a transmission electron microscope, it was confirmed that an oxidized film with 8 nm thickness and an Au-layer with 10 nm thickness thereon were present on the surface of the Ti substrate, and formation of the oxidized film and the conductive film (regenerated conductive film 3A) by the continuous treatment in the vacuum processing chamber could be confirmed.

TABLE 1

| | | Manufacturing/regenerating condition of separator | | | | | | |
|---|---|---|---|---|---|---|---|---|
| | | | Substrate | Oxidized film | | | | |
| | | | removing | | Film | Conductive film | | Heat |
| | New/ | Removing | thickness | | thickness | | Thickness | treatment |
| Example No. | Regenerated | condition | (nm) | Forming condition | (nm) | Material | (nm) | condition |
| Example 1 | New | — | — | 0.25% HF + 1.0% | — | Au | 10 | 400° C. × |
| | | | | HNO₃ × 1 min | | | | 3 min |
| | Regenerated | Ar ion beam | 56 | O₂ plasma × 5 min | 8 | Au | 10 | 400° C. × |
| | | irradiation × 5 min | | | | | | 3 min |
| Example 2 | New | — | — | 0.25% HF + 1.0% | — | Au | 10 | 400° C. × |
| | | | | HNO₃ × 1 min | | | | 3 min |
| | Regenerated | Ar ion beam | 51 | 1 N HNO₃ × 10 min | 6 | Au | 10 | 400° C. × |
| | | irradiation × 5 min | | | | | | 3 min |
| Example 3 | New | — | — | 0.25% HF + 1.0% | — | Au | 10 | 400° C. × |
| | | | | HNO₃ × 1 min | | | | 3 min |
| | Regenerated | 0.25% HF + 1.0% | 890 | — | 8 | Au | 10 | 400° C. × |
| | | HNO₃ × 3 min | | | | | | 3 min |
| Example 4 | New | — | — | 0.25% HF + 1.0% | — | Au | 10 | 400° C. × |
| | | | | HNO₃ × 1 min | | | | 3 min |
| | Regenerated | 80° C., 10% H₂SO₄ × | 380 | — | 7 | Au | 7 | 400° C. × |
| | | 30 min | | | | | | 3 min |
| Example 5 | New | (Ar ion beam | — | — | — | Au—Ta | 30 | — |
| | | irradiation × 5 min) | | | | | | |
| | Regenerated | Ar ion beam | 64 | — | — | Au—Ta | 30 | — |
| | | irradiation × 8 min | | | | | | |

| | | | | | | Fuel cell generation voltage (V) | | |
|---|---|---|---|---|---|---|---|---|
| | | Contact resistance of separator (mΩ) | | | | Initial | Final | |
| | | Before | | | | stage | stage | |
| | New/ | heat | Before | After | | of | of | |
| Example No. | Regenerated | treatment | operation | operation | Increment Δ | operation | operation | Decrement Δ |
| Example 1 | New | 27 | 4.6 | 5.1 | 0.5 | 0.612 | 0.608 | 0.004 |
| | Regenerated | 22 | 4.2 | 4.8 | 0.6 | 0.611 | 0.606 | 0.005 |
| Example 2 | New | 31 | 4.8 | 5.4 | 0.6 | 0.615 | 0.610 | 0.005 |
| | Regenerated | 29 | 4.5 | 5.2 | 0.7 | 0.616 | 0.610 | 0.006 |
| Example 3 | New | — | 4.4 | 5.0 | 0.6 | 0.613 | 0.609 | 0.004 |
| | Regenerated | 35 | 4.7 | 5.1 | 0.4 | 0.615 | 0.611 | 0.004 |
| Example 4 | New | — | 4.6 | 5.5 | 0.9 | 0.612 | 0.608 | 0.004 |
| | Regenerated | 44 | 4.9 | 5.5 | 0.6 | 0.608 | 0.602 | 0.006 |
| Example 5 | New | — | 3.8 | 4.6 | 0.8 | 0.520 | 0.513 | 0.007 |
| | Regenerated | — | 3.9 | 4.8 | 0.9 | 0.518 | 0.510 | 0.008 |

Note:
“—” mean “not performed” or “not measured”.

### Example 2

In Example 2, the new separator with same specification of that of Example 1 was manufactured, and, similarly to Example 1, was assembled into the fuel cell shown in FIG. 1, and 5,000 hours of operation and power generation were performed on the fuel cell. The contact resistance before and after the operation and the increased amount Δ, the voltage in the early stage of operation and after the 5,000 hours of operation as well as the drop amount Δ of the voltage are shown in Table 1. With respect to both of the contact resistance and generation voltage, properties of the same level with those of the new separator in Example 1 were recognized.

(Removing Step)

The recovered separator was placed in the composite type treatment system shown in FIG. 3, and the Au-film and the oxidized film as well as the surface of the Ti substrate were removed by irradiation of an Ar ion beam under the condition same to that of the removing step in Example 1. Also, the removing thickness of the surface of the substrate by the removing step was calculated by the method similar to that in Example 1. The removing thickness of the surface of the substrate was 51 nm per one side.

(Oxidizing Step)

Next, the substrate (regenerated substrate 2A) was taken out from the processing chamber, was immersed in 1N nitric acid for 10 min at ordinary temperature to form the passivated film on the surface, and was water washed and dried after immersion.

(Film-Forming Step)

Then, the substrate was placed in the composite type treatment system shown in FIG. 3, and an Au film with 10 nm thickness was formed under the condition same to that in the manufacturing step for the new separator. Also, film-forming was performed in the similar manner on the back side of the substrate as well.

(Heat Treatment Step)

Finally, heat treatment was performed under the condition same with that of manufacturing the new separator, and the regenerated separator was manufactured. Also, the contact resistance before and after the heat treatment step was measured by the method similar to that for the new separator. As shown in Table 1, respective contact resistance was 29 mΩ and 4.5 mΩ suggesting formation of the passivated film between the Ti substrate (regenerated substrate 2A) and the Au film (regenerated conductive film 3A) by having been immersed in the nitric acid, further, improvement in conductivity of the same level with that in the heat treatment for the new separator was realized by the heat treatment. Also, the regenerated separator obtained was recognized to have the conductivity of the same level with that of the new separator.

(Reuse for Fuel Cell and Operation)

Similarly to the new separator, the regenerated separator was assembled into the fuel cell shown in FIG. 1, and 5,000 hours of power generation operation was performed. The voltage in the early stage of operation and after 5,000 hours of operation as well as the drop amount Δ of the voltage are shown in Table 1. After the 5,000 hours of operation, the fuel cell was disassembled, the separators were recovered, and the contact resistance was measured by the method similar to that before operation. The contact resistance and the increased amount Δ from the contact resistance before operation are shown in Table 1.

As shown in Table 1, the generation voltage in the early stage and the final stage of operation were 0.616 V, 0.610 V respectively, and the drop amount was 0.006 V. Also, the contact resistance was 5.2 mΩ which was 0.7 mΩ increase compared with that before operation. Thus, the properties of the same level with those of the new separator were obtained with respect to both of the generation voltage and the drop amount by the operation and the contact resistance and the increased amount by the operation. Further, by observation of the cross-section of the recovered separator by a transmission electron microscope, it was confirmed that an oxidized film with 6 nm thickness and an Au layer with 10 nm thickness thereon were present on the surface of the Ti substrate, and formation of the passivated film by immersion in an oxidizing acid after removal of the conductive film could be confirmed.

### Example 3, Example 4

In Example 3 and Example 4, the new separator with the specification same to that of Example 1 was manufactured and, similarly to Example 1, was assembled into the fuel cell shown in FIG. 1, and 5,000 hours of operation and power generation were performed on the fuel cell. The contact resistance before and after the operation and the increased amount Δ, the voltage in the early stage of the operation and after the 5,000 hours of operation as well as the drop amount Δ of the voltage are shown in Table 1. With respect to both of the contact resistance and generation voltage, properties of the same level with those of the new separator in Example 1 were recognized.

(Removing Step and Oxidizing Step)

In Example 3, by immersing the recovered separator in an aqueous solution of nitric-hydrofluoric acid, mixture of 0.25% HF and 1.0% HNO₃, for 3 min at ordinary temperature, the Au film was removed, whereas in Example 4, the Au film was removed by immersing the recovered separator in an aqueous solution of 10% sulfuric acid at 80 DEG C. for 30 min. These separators (regenerated substrates 2A) were water washed and dried. The result of the component analysis by SEM-EDX on the surface of respective regenerated substrate of Example 3 and Example 4 shows that the peak of Au was not present, and Au was confirmed to have been entirely removed respectively.

Also, the removing thickness of the surface of the substrate by the removing step was calculated by measuring the weight of the substrate after formation of the oxidized film in the step for manufacturing respective new separator of Example 3 and Example 4, measuring the weight of the substrate again after this oxidizing step, calculating the removed weight of the substrate based on the difference between these weights, and thereafter dividing the removed weight by the surface area of the separator and the density of Ti. The removing thickness of the surface of the substrate thus calculated was 890 nm in Example 3 and 380 nm in Example 4 per one side.

(Film-Forming Step)

Then, the regenerated substrate was placed in the composite type treatment system shown in FIG. 3, and an Au film was formed under the condition same to that of Example 1. The film thickness was 10 nm for Example 3 and 7 nm for Example 4. Also, film-forming was performed in the similar manner on the back side of the regenerated substrate as well. Thereafter, the contact resistance of the regenerated substrate after film-forming was measured by the method similar to that of Example 1. The result is shown in Table 1. The contact resistance was as high as 35 mΩ in Example 3 and 44 mΩ in Example 4 which suggested formation of the passivated film between the Ti substrate (regenerated substrate 2A) and the Au film (regenerated conductive film 3A) respectively.

(Heat Treatment Step)

Finally, heat treatment was performed under the condition same with that of manufacturing the new separator, and the regenerated separator was manufactured. With respect to the regenerated separator also, the contact resistance was measured by the method similar to that for the new separator. The result is shown in Table 1. The contact resistance lowered to 4.7 mΩ in Example 3 and to 4.9 mΩ in Example 4 respectively, and it was recognized that conductivity of the passivated film had improved by the heat treatment to the similar level as that of the regenerated separator in Example 1.

(Reuse for Fuel Cell and Operation)

Similarly to the new separator, the regenerated separator was assembled into the fuel cell shown in FIG. 1, and 5,000 hours of power generation operation was performed. The voltage in the early stage of operation and after 5,000 hours of operation as well as the drop amount Δ of the voltage are shown in Table 1. After the 5,000 hours of operation, the fuel cell was disassembled, the separators were recovered, and the contact resistance was measured by the method similar to that before operation. The contact resistance and the increased amount Δ from the contact resistance before operation are shown in Table 1.

As shown in Table 1, the generation voltage in both of the early stage and the final stage of the operation were 0.6 V or above, and the drop amount was 0.004 V in Example 3 and 0.006 V in Example 4. Also, the contact resistance after the operation was 5.1 mΩ, which was 0.4 mΩ increase, in Example 3. It was 5.5 mΩ, which was 0.6 mΩ increase, in Example 4. Thus, the properties of the same level with those of the new separator were obtained with respect to both of the generation voltage and the drop amount by the operation and the contact resistance and the increased amount by the operation. Further, by observation of the cross-section of the recovered separator by a transmission electron microscope, it was confirmed that an oxidized film with 8 nm thickness on the surface of the Ti substrate and an Au layer with 10 nm thickness thereon were present in Example 3. Also, in Example 4, it was confirmed that an oxidized film with 7 nm thickness on the surface of the Ti substrate and an Au-layer with 7 nm thickness thereon were present. Thus, formation of the passivated film by immersion in an acid after removal of the Au layer (the conductive film 3) could be confirmed.

### Example 5

Next, Example 5 will be described.

### {Manufacturing of Separator}

Pure Ti substrate same with those in Examples 1-4 was used for the substrate of the new separator.

(Removal of Passivated Film)

The passivated film formed on the surface of the Ti substrate (substrate 2) was removed by irradiation of an Ar ion beam. More specifically, the substrate was placed in the composite type treatment system shown in FIG. 3 (ion gun—separator distance: 20 cm), and the Ar ion beam was irradiated onto the surface of the substrate under the same condition with that of the removing step in regeneration in Example 1.

(Formation of Conductive Film)

While the substrate was placed in the composite type treatment system, continuously, the conductive film 3 was formed by sputtering. An Au and Ta alloy film (50 atm % of Ta component) was formed using an Au target and a Ta target with 4 inch diameter and 5 mm thickness respectively at the same time. The targets and the substrate 2 were disposed beforehand so that the distance between them becomes 20 cm respectively. Similarly to Examples 1-3, after inside of the processing chamber was evacuated to 1.3×10⁻³ Pa or below again, Ar gas was introduced up to 0.266 Pa. Then, while the substrate 2 was rotated at the rotational speed of 15 rpm, film was formed to 30 nm film thickness by 100 W Au target output and 200 W Ta target output. Further, also on the back side of the substrate, the passivated film was removed and an Au—Ta alloy film was formed in the similar manner, and thereby, the new separator was manufactured.

The contact resistance of the new separator manufactured was measured. The result is shown in Table 1. Because the passivated film was not present, the contact resistance was as low as 3.8 mΩ and good conductivity was realized.

(Reuse for Fuel Cell and Operation)

Similarly to Examples 1-4, the new separator was assembled into the fuel cell shown in FIG. 1. Instead of hydrogen in Examples 1-4, 20 mass % aqueous solution of methanol was supplied to the fuel assembled. Then, 5,000 hours of power generation operation was performed while keeping the current passing the separator constant at 60 mA/cm² with other conditions remaining unchanged from Examples 1-3. The voltage in the early stage of operation and after 5,000 hours of operation as well as the drop amount Δ of the voltage are shown in Table 1. After the 5,000 hours of operation, the fuel cell was disassembled, the separators were recovered, and the contact resistance was measured by the method similar to that before operation. The contact resistance and the increased amount Δ from the contact resistance before operation are shown in Table 1.

As shown in Table 1, the generation voltage in the early stage and the final stage of the operation were 0.520 V, 0.513 V respectively, and the drop amount was 0.007 V. Also, the criterion for the generation voltage in the fuel cell using methanol as the fuel in accordance with the present Example is 0.5 V or above in the early stage of the operation and 0.01 V or below for the drop amount. Further, the contact resistance was 4.6 mΩ which was 0.8 mΩ increase compared with that before operation, however, no significant deterioration in conductivity was recognized.

Next, the recovered separator was regenerated by the method in accordance with the present invention.

(Removing Step and Film-Forming Step)

The recovered separator was placed in the composite type treatment system shown in FIG. 3, and the Au—Ta alloy film was removed by irradiation of an Ar ion beam under the condition same to that in removal of the passivated film in manufacturing the new separator of the present Example. However, irradiation time was made 8 min. Then, continuously, the Au—Ta alloy film (regenerated conductive film 3A) with 30 nm thickness was formed by sputtering under the condition same to that in film-formation of the conductive film in manufacturing the new separator likewise. On the back side of the separator also, the Au—Ta alloy film was removed and new Au—Ta alloy film was formed in the same manner, thereby the regenerated separator was manufactured. Then the contact resistance of the regenerated separator manufactured was measured. The result is shown in Table 1. The contact resistance was 3.9 mΩ, and conductivity of the same level with that of the new separator was realized. Further, the removing thickness of the surface of the substrate by the removing step was calculated by the method similar to that in Example 1. The removing thickness of the surface of the substrate was 64 nm per one side.

(Reuse for Fuel Cell and Operation)

Similarly to the new separator, the regenerated separator was assembled into the fuel cell shown in FIG. 1, and 5,000 hours of power generation operation was performed. The voltage in the early stage of the operation and after the 5,000 hours of operation as well as the drop amount Δ of the voltage are shown in Table 1. After the 5,000 hours of operation, the fuel cell was disassembled, the separators were recovered, and the contact resistance was measured by the method similar to that before operation. The contact resistance and the increased amount Δ from the contact resistance before the operation are shown in Table 1.

As shown in Table 1, the generation voltage in the early stage and the final stage of the operation were 0.518 V, 0.510 V respectively, and the drop amount was 0.008 V. Also, the contact resistance was 4.8 mΩ which was 0.9 mΩ increase compared with that before the operation. Thus, the properties of the same level with those of the new separator were obtained with respect to both of the generation voltage and the drop amount by the operation and the contact resistance and the increased amount by the operation.

What is claimed is:

1. A method for regenerating a separator for a fuel cell, the separator being composed of a substrate of Ti or Ti alloy and a conductive film formed thereon, which comprises a removing step of removing the conductive film from the separator for a fuel cell and also removing part of the surface of the substrate, thereby giving a regenerated substrate, and a film-forming step of forming a regenerated conductive film on the regenerated substrate, the conductive film and the regenerated conductive film being at least one species of noble metal or alloy thereof selected from the group of noble metals consisting of Au, Pt, and Pd, or an alloy composed of at least one species selected from the group of noble metals and one species selected from the group of metals consisting of Ti, Zr, Hf, Nb, Ta, and Si.

2. The method as set forth in claim 1 further comprising an oxidizing step for forming an oxidized film on the surface of the regenerated substrate after the removing step, wherein in the film-forming step, the regenerated conductive film is formed on the surface of the oxidized film.

3. The method as set forth in claim 2, wherein the oxidizing step is performed by exposing the regenerated substrate in plasma including oxygen.

4. The method as set forth in claim 2, wherein the oxidizing step is performed by immersing the regenerated substrate in an aqueous solution including an oxidizing acid and a passivated film is formed as the oxidized film.

5. The method as set forth in claim 4, wherein at least one kind selected from a nitric acid and a sulfuric acid is used as the oxidizing acid.

6. The method as set forth in claim 1, wherein the removing step is performed by: generating plasma including at least one kind of a rare gas element selected from a group consisting of Ne, Ar, Kr, Xe in the circumstance of the separator for a fuel cell by applying negative bias voltage to the separator for a fuel cell; and making ions of the rare gas element generated in the plasma collide with the surface of the separator for a fuel cell.

7. The method as set forth in claim 5, wherein the removing step is performed by: generating plasma including at least one kind of a rare gas element selected from a group consisting of Ne, Ar, Kr, Xe in the circumstance of the separator for a fuel cell by applying negative bias voltage to the separator for a fuel cell; and making ions of the rare gas element generated in the plasma collide with the surface of the separator for a fuel cell.

8. The method as set forth in claim 1, wherein the removing step is performed by irradiating an ion beam of at least one kind of a rare gas element selected from a group consisting of Ne, Ar, Kr, Xe onto the surface of the separator for a fuel cell.

9. The method as set forth in claim 5, wherein the removing step is performed by irradiating an ion beam of at least one kind of a rare gas element selected from a group consisting of Ne, Ar, Kr, Xe onto the surface of the separator for a fuel cell.

10. The method as set forth in claim 2, wherein the removing step and the oxidizing step are performed continuously by immersing the separator for a fuel cell in a solution including at least one kind of ion selected from a group consisting of Cl⁻, F⁻, NO₃⁻, SO₄²⁻.

11. The method as set forth in claim 2 further comprising a heat treatment step for performing a heat treatment at a temperature of 300-600 DEG C. on a regenerated substrate with the regenerated conductive film being formed by the film-forming step.

12. The method as set forth in claim 1 further comprising a heat treatment step for performing a heat treatment at a temperature of 300-600 DEG C. on a regenerated substrate with the regenerated conductive film being formed by the film-forming step.

13. The method as set forth in claim 1, wherein in the film-forming step, the regenerated conductive film is formed by a sputtering method so that its thickness becomes 2-200 nm.

14. The method as set forth in claim 12, wherein in the film-forming step, the regenerated conductive film is formed by a sputtering method so that its thickness becomes 2-200 nm.

15. A regenerated separator for a fuel cell formed through the steps of removing from a separator for a fuel cell composed of a substrate of Ti or Ti alloy and a conductive film formed thereon, the conductive film and part of the surface of the substrate, and forming a regenerated conductive film on the thus removed separator for a fuel cell,
wherein
the conductive film and the regenerated conductive film are at least one species of noble metal or alloy thereof selected from the group of noble metals consisting of Au, Pt, and Pd, or an alloy composed of at least one species selected from the group of noble metals and one species selected from the group of metals consisting of Ti, Zr, Hf, Nb, Ta, and Si, and
wherein
the conductive film and part of the surface of the substrate are removed by making ions of at least one kind of a rare gas element selected from a group consisting of Ne, Ar, Kr, Xe collide with the surface of the separator for a fuel cell under reduced pressure.

16. The regenerated separator as set forth in claim 15, wherein an oxidized film is formed on a surface of the separator for a fuel cell from which the conductive film and part of the surface of the substrate has been removed, and on the surface of the oxidized film the conductive film is formed.

17. A regenerated separator for a fuel cell formed through the steps of removing from a separator for a fuel cell composed of a substrate of Ti or Ti alloy and a conductive film formed thereon, the conductive film and part of the surface of the substrate, and forming an oxidized film and further a regenerated conductive film on the thus removed separator for a fuel cell,
wherein
the conductive film and the regenerated conductive film being at least one species of noble metal or alloy thereof selected from the group of noble metals consisting of Au, Pt, and Pd, or an alloy composed of at least one species selected from the group of noble metals and one species selected from the group of metals consisting of Ti, Zr, Hf, Nb, Ta, and Si, and
wherein
the conductive film and part of a surface of the substrate are removed by immersing the separator for a fuel cell in a solution including at least one kind of ions selected from a group consisting of Cl⁻, F⁻, NO₃⁻, SO₄²⁻, and the oxidized film is formed by immersing the separator for a fuel cell in the solution.

18. The regenerated separator as set forth in claim 16, wherein a heat treatment is performed at the temperature of 300-600 DEG C. after the regenerated conductive film is formed.

19. The regenerated separator as set forth in claim 17, wherein a heat treatment is performed at the temperature of 300-600 DEG C. after the regenerated conductive film is formed.

20. A fuel cell using the regenerated separator for a fuel cell as set forth in any one of claims 15 to 19.
